(19) United States
(12) Patent Application Publication
(10) Pub. No.: US 2008/0297175 A1
(43) Pub. Date: Dec. 4, 2008

(54) APPARATUS AND METHOD FOR MEASURING CAPACITANCE TO GROUND OF CONDUCTOR

(76) Inventor: Yingchao WU, Shenzhen (CN)

Correspondence Address: YH CHAN, 42 PIN OAKS DRIVE, PHOENIXVILLE, PA, 19460, US

(21) Appl. No.: 12/122,716

(22) Filed: May 18, 2008

(30) Foreign Application Priority Data
May 31, 2007 (CN) 200710074712.8

(51) Int. Cl. G01R 27/26

(52) U.S. Cl. 324/686

(57) ABSTRACT

Apparatus and method for measuring the capacitance to ground of a conductor are disclosed. The apparatus includes at least three switching elements, a voltage measurement circuit, and a controller. Two terminals of a first switching element are connected respectively to a distal terminal of a sample capacitor and a first voltage. Two terminals of a second switching element are connected respectively to a proximal terminal of the sample capacitor and a second voltage. Two terminals of a third switching element are connected respectively to the proximal terminal and the first voltage. The proximal terminal is directly electrically connected to one conductor end. The conductor has an unknown capacitance to ground representative of an object to be sensed. The change in the capacitance of the unknown capacitance capacitor can be determined and a proximity or contact of the object can thus be sensed by using the above apparatus and method.

### BACKGROUND OF THE INVENTION

The present invention relates to apparatuses and methods for measuring capacitance, and more particularly, to an apparatus and a method for measuring capacitance to ground of a conductor.

U.S. Pat. No. 6,466,036 B1, issued on Oct. 15, 2002 and entitled “Charge Transfer Capacitance Measurement Circuit”, proposes a circuit apparatus for measuring the capacitance to ground of a conductor by transferring charge and a charge measurement method. The proposed circuit apparatus includes at least three switching elements, a first capacitor, and a voltage measurement circuit. Each of the at least three switching elements has both a respective open state and a single respective closed state. Each of the at least three switching elements is electrically connected to one of two distinct reference voltages. The first capacitor has two terminals. A proximal one of the two terminals is directly connected to the conductor. That is, no switching elements are interposed between the proximal terminal and the conductor. The second terminal is distal from the conductor. The voltage measurement circuit is directly connected to one of the terminals of the first capacitor. That is, no switching elements are interposed between the voltage measurement circuit and the one terminal of the first capacitor. The voltage measurement circuit includes one of a logic gate and a voltage comparator. Two terminals of a first of the at least three switching elements are connected respectively to the distal terminal of the first capacitor and a first reference voltage of the two distinct reference voltages. The first switching element connects the distal terminal of the first capacitor to the first reference voltage when in its closed state and disconnects the distal terminal from the first reference voltage when in its open state. Two terminals of a second of the at least three switching elements are connected respectively to the proximal terminal of the first capacitor and a second reference voltage of the two distinct reference voltages. The second switching element connects the proximal terminal of the first capacitor to the second reference voltage when in its closed state and disconnects the proximal terminal from the second reference voltage when in its open state. Two terminals of a third of the at least three switching elements are connected respectively to the distal terminal of the first capacitor and the second reference voltage. The third switching element connects the distal terminal of the first capacitor to the second reference voltage when in its closed state and disconnects the distal terminal from the second reference voltage when in its open state. The circuit apparatus further includes a controller for operating the at least three switching elements so that at any time at least one of the at least three switching elements is in its respective open state.

By measuring and calculating the unknown capacitance, the circuit apparatus described above can determine a change in the capacitive value, thereby sensing a proximity or contact of an object to be sensed.

### BRIEF SUMMARY OF THE INVENTION

In one aspect, an apparatus for measuring the capacitance to ground of a conductor is provided. The apparatus comprises at least three switching elements including first, second and third switching elements, a first capacitor, a voltage measurement circuit, and a controller. Each of the first, second and third switching elements has both a respective open state and a single respective closed state. One terminal of each of the first, second and third switching elements is electrically connected to one of first and second distinct voltages. The first capacitor has two terminals and has a given capacitance. One of the two terminals of the first capacitor is electrically connected to another terminal of each of the first, second and third switching elements. A proximal one of the two terminals of the first capacitor is directly electrically connected to one end of a conductor by means not comprising one of the switching elements. The other terminal of the two terminals is distal from the conductor. The conductor has an unknown capacitance to ground. In brief, the unknown capacitance capacitor is called the second capacitor. The voltage measurement circuit is directly electrically connected to one of the two terminals of the first capacitor by means not comprising one of the switching elements. The controller is configured for operating the first, second and third switching elements so that at any time at least one of the first, second and third switching elements is in its respective open state.

The two terminals of the first switching element are connected respectively to the distal terminal of the first capacitor and the first voltage. The first switching element connects the distal terminal of the first capacitor to the first voltage when in its closed state and disconnects the distal terminal from the first voltage when in its open state. The two terminals of the second switching element are connected respectively to the proximal terminal of the first capacitor and the second voltage. The second switching element connects the proximal terminal of the first capacitor to the second voltage when in its closed state and disconnects the proximal terminal from the second voltage when in its open state. The two terminals of the third switching element are connected respectively to the proximal terminal of the first capacitor and the first voltage. The third switching element connects the proximal terminal of the first capacitor to the first voltage when in its closed state and disconnects the proximal terminal from the first voltage when in its open state.

According to one embodiment of the invention, the first voltage is a given DC supply voltage, and the second voltage is a given DC supply voltage higher than the first voltage.

According to another embodiment of the invention, the second voltage is a given DC supply voltage, and the first voltage is a given DC supply voltage higher than the second voltage.

According to still another embodiment of the invention, each of the first, second and third switching elements comprises a respective field effect transistor, and the controller comprises a clocked voltage pulse source.

In another aspect, a method for measuring the capacitance to ground of a conductor using the measuring apparatus is provided. The first voltage is a given DC supply voltage, and the second voltage is a given DC supply voltage higher than the first voltage. The method includes the steps of:

a) resetting the first capacitor by closing both the first switching element and the third switching element and opening the second switching element to thereby connect both the distal and proximal terminals of the first capacitor to the first voltage;

b) opening both the first switching element and the third switching element;

c) closing the second switching element, waiting an interval having a selected duration and thereafter opening the second switching element;

d) charging the first capacitor by closing the first switching element for an interval having a selected duration;

e) measuring a voltage difference across the first capacitor using the voltage measurement circuit, the voltage difference representative of the capacitance to ground of the conductor.

In one preferred embodiment, the method further includes a step f), subsequent to step e), of repeating steps b), c), d), e) a selected number of times.

In another preferred embodiment, the method further includes a step d1), intermediate steps d) and e), of repeating steps b), c), d) a selected number of times, wherein the step d1) proceeds to step e) after the selected number of times of the repeating is completed.

In still another preferred embodiment, the method further includes a step c0), prior to step c), of changing the amount of the charges on the first capacitor by a selected amount.

In another aspect, a method for measuring the capacitance to ground of a conductor using the measuring apparatus is provided. The second voltage is a given DC supply voltage, and the first voltage is a given DC supply voltage higher than the second voltage. The method includes the steps of:

a) resetting the first capacitor by closing both the first switching element and the third switching element and thereby connecting both the distal and proximal terminals of the first capacitor to the first voltage;

b) opening all of the first, second, and third switching elements;

c) charging the first capacitor by closing the first switching element, waiting an interval having a selected duration and thereafter opening the first switching element;

d) closing the second switching element, and waiting a selected interval;

e) measuring a voltage difference across the first capacitor using the voltage measurement circuit, the voltage difference representative of the capacitance to ground of the conductor.

In one preferred embodiment, the method further includes a step f), subsequent to step e), of repeating steps b), c), d), e) a selected number of times.

In another preferred embodiment, the method further includes a step d1), intermediate steps d) and e), of repeating steps b), c), d) a selected number of times, wherein the step d1) proceeds to step e) after the selected number of times of the repeating is completed.

In still another preferred embodiment, the method further includes a step c0), prior to step c), of changing the amount of the charges on the first capacitor by a selected amount.

In still another aspect, a method for measuring the capacitance to ground of a conductor using the measuring apparatus is provided. The first voltage is a given DC supply voltage, and the second voltage is a given DC supply voltage higher than the first voltage. The method includes the steps of:

a) closing both the first switching element and the second switching element for an interval having a selected duration so that the first capacitor stores a selected amount of charges;

b) opening both the first and second switching elements;

c) closing the third switching element for an interval having a selected duration and thereafter opening the third switching element;

d) discharging the first capacitor by closing the first switching element for an interval having a selected duration;

e) measuring a voltage difference across the first capacitor using the voltage measurement circuit, the voltage difference representative of the capacitance to ground of the conductor.

In one preferred embodiment, the method further includes a step f), subsequent to step e), of repeating steps b), c), d), e) a selected number of times.

In another preferred embodiment, the method further includes a step d1), intermediate steps d) and e), of repeating steps b), c), d) a selected number of times, wherein the step d1) proceeds to step e) after the selected number of times of the repeating is completed.

In still another preferred embodiment, the method further includes a step c0), prior to step c), of changing the amount of the charges on the first capacitor by a selected amount.

By measuring and calculating the unknown capacitance of the second capacitor representative of an object to be sensed using the apparatus and method described above, the change in the capacitance of the second capacitor can be determined and a proximity or contact of the object can thus be sensed.

### BRIEF DESCRIPTION OF THE DRAWINGS

FIG. 1 is a schematic block circuit diagram showing one implementation of the apparatus.

FIG. 2 is a schematic block circuit diagram showing another implementation of the apparatus.

### DETAILED DESCRIPTION OF THE INVENTION

Glossary of Terms

Cs: a capacitor having a given capacitance, also referred to as a sample capacitor or a first capacitor.

Cx: a capacitor having an unknown capacitance to be measured, also referred to as a second capacitor.

Vcs (n): a voltage difference across the Cs after n times of charge transfer, where n is from 1 to N.

ΔVcs (n): an incremental voltage on Vcs defined by Vcs (n)−Vcx (n−1), where n is from 2 to N.

The circuit apparatus of the present method is used to provide an indication of the proximity or movement of a person or object to be sensed. This is achieved by measuring a change in the capacitive value of a second capacitor Cx having an unknown capacitance, or a second capacitor Cx generated between a conductor and the ground. The circuit apparatus of the present invention includes at least three switching elements and two distinct given direct current voltages. The circuit apparatus further includes a first capacitor Cs having a given capacitance, a voltage measurement circuit, and a control circuit. The first capacitor Cs has two terminals. One of the two terminals is directly electrically connected to the conductor by means not comprising one of the switching elements. That is, no switching elements are interposed between the one terminal and the conductor. This one terminal is referred to herein as a proximal terminal of the capacitor, while the other terminal is referred to as a distal terminal of the capacitor.

The control circuit includes a controller for operating the at least three switching elements so that at any time at least one of the at least three switching elements is in its respective open state. A first switching element S1 of the at least three switching elements has two terminals that are connected respectively to the distal terminal of the first capacitor Cs and a first voltage V1. The first switching element S1 connects the distal terminal of the first capacitor Cs to the first voltage V1 when in its closed state and disconnects the distal terminal from the first voltage V1 when in its open state. A second switching element S2 of the at least three switching elements has two terminals that are connected respectively to the proximal terminal of the first capacitor Cs and a second voltage V2. The second switching element S2 connects the proximal terminal of the first capacitor Cs to the second voltage V2 when in its closed state and disconnects the proximal terminal from the second voltage V2 when in its open state. A third switching element S3 of the at least three switching elements has two terminals that are connected respectively to the proximal terminal of the first capacitor Cs and the first voltage V1. The third switching element S3 connects the proximal terminal of the first capacitor Cs to the first voltage V1 when in its closed state and disconnects the proximal terminal from the first voltage V1 when in its open state. In one embodiment, each of the first, second and third switching elements S1 to S3 includes a respective field effect transistor (FET). The controller includes a clocked voltage pulse source.

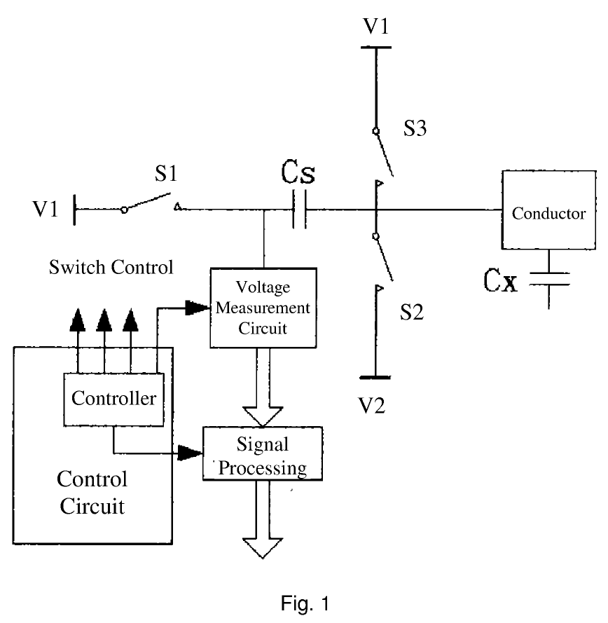

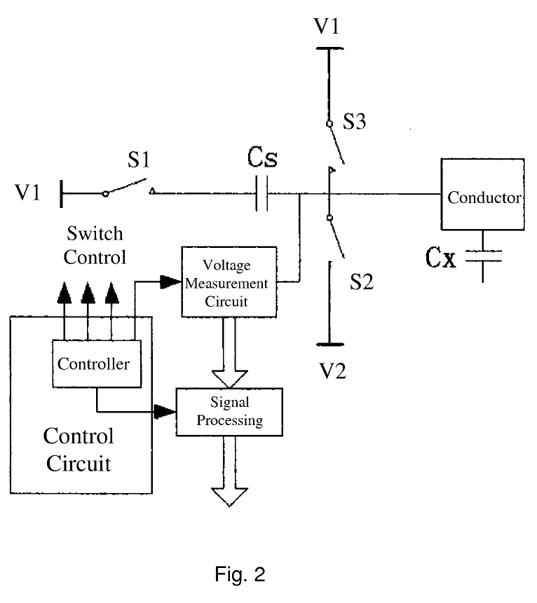

FIG. 1 depicts one implementation in which the voltage measurement circuit is connected to the distal terminal of the first capacitor Cs. FIG. 2 depicts another implementation in which the voltage measurement circuit is connected to the proximal terminal of the first capacitor Cs. In practice, the voltage measurement circuit connected to either terminal of the first capacitor Cs, as depicted in FIG. 1 and FIG. 2, can measure the voltage difference across the first capacitor Cs. In the exemplary implementations illustrated in FIGS. 1 and 2 and described herein, only three switching elements are employed. It is noted that the three switching elements are for the purpose of description only and the number of the switching elements should not be regarded as limiting.

As shown in FIG. 1 and FIG. 2, both a conductor and an unknown capacitor Cx are depicted. However, it is noted that the conductor and unknown capacitor Cx are not part of the circuit apparatus of the present invention and they represent the capacitance of an object to be sensed. It is also noted that in these depictions Cx is the capacitance of the conductor to free space or to an electrical ground. The control circuit controls the switching sequence of the switching elements and also the operation of the voltage measurement circuit. A signal process module may often be required to translate an output of the measurement circuit into a usable form. For example, this may involve converting cycle counts into a binary representation of signal strength.

Table 1, Table 2, and Table 3 show the switching sequences in different actual applications, respectively.

In Table 1, the Second Voltage V2 is a given direct current (DC) supply voltage higher than the First Voltage V1. First, in step A, the first switching element S1 and second switching element S3 are closed to clear or discharge charges on Cs. In step C, the second switching element S2 is closed to charge the second capacitor Cx with the Second Voltage V2 such that the voltage level at the connection of the second capacitor Cx and the second switching element S2 is higher than the First Voltage V1. After waiting an interval having a selected duration, the second switching element S2 opens so that a certain amount of charges are left on the second capacitor Cx. In step D, the first switching element S1 is closed. Since the distal terminal of the first capacitor Cs has a voltage level of the First Voltage V1, a voltage difference Vr exists across the first capacitor Cs, and thus the first capacitor Cs is charged by the second capacitor Cx. After an interval having a selected duration, a part of the charges are transferred from the second capacitor Cx to the first capacitor Cs. In practice, the capacitance of the second capacitor Cx is rather small such that Cs>>Cx. Therefore, the amount of charges transferred during each transfer cycle is also rather small, making it difficult to measure the voltage difference across the first capacitor Cs. In the illustrated embodiment, the process of charging the second capacitor Cx and subsequently transferring the charges to the first capacitor Cs is cycled repeatedly in order to build up the charges on the first capacitor Cs. This provides a larger measurable voltage difference across the first capacitor Cs which can be readily measured.

TABLE 1
First voltage is a given DC supply voltage, and Second voltage
is a given DC supply voltage higher than First voltage.

| STEP | S1 | S2 | S3 | FUNCTION |
|---|---|---|---|---|
| A | Close | Open | Close | Reset Cs |
| B | Open | Open | Open | Deadtime |
| C | Open | Close, | Open | Charge |
| | | then Open | | |
| D | Close | Open | Open | Charge Transfer |
| E | | | | Measure voltage |
| | | | | across Cs |
| F | | | | Repeat BCDE |

Equations used in calculating the capacitance of the second capacitor Cx according to the switching sequence of Table 1 are as follows:

ΔVcs(1)=Vr·Cx/(Cs+Cx)

ΔVcs(n)=K(Vr−Vcs(n−1))

K=Cx/(Cs+Cx)

Vcs(N)=ΔVcs(1)+ΔVcs(2)+ΔVcs(3)+ . . . +ΔVcs(N),

where Vcs (N) can be obtained by voltage measurement, N is a known number of repeating cycles, and Vr is a known constant. Thus, the capacitance of the second capacitor Cx can be obtained by the above mathematics operation.

In practice, it is usually unnecessary to know the exact capacitive value of the second capacitor Cx. Rather, it is often desired to measure a change in the capacitive value of the second capacitor Cx. In one embodiment, to measure this change, the charge transfer is terminated after a fixed number of transfer cycles and, subsequently, the voltage difference Vcs across the first capacitor Cs is measured. The change in the capacitive value of the second capacitor Cx can thus be determined by measuring the change in the Vcs value. In another embodiment, the charge transfer is terminated after the Vcs has risen to a preset fixed voltage level. The change in the capacitive value of the second capacitor Cx can thus be determined by calculating the number of transfer cycles.

In Table 2, the First Voltage V1 is a given DC supply voltage higher than the Second Voltage V2. First, in step A, the first switching element S1 and second switching element S3 are closed to clear charge on Cs. In step C, when only the first switching element S1 is closed, the second capacitor Cx and the first capacitor Cs that are connected in series are charged by the First Voltage V1. After waiting an interval having a selected duration, the first switching element S1 opens so that a certain amount of charges are left on both the second capacitor Cx and the first capacitor Cs. Kirchoff's current law and the principle of charge conservation dictate that the charges on the second capacitor Cx and the charges on the first capacitor Cs are equal. A reference voltage at the distal terminal of the first capacitor Cs with respect to the Second Voltage V2 is referred to as Vr. In step D, the second switching element S2 is closed to clear the charges on the second capacitor Cx. After an interval having a selected duration, the voltage at the proximal terminal of the first capacitor Cs is restored to the Second Voltage V2. Steps B through D are repeated a selected number of times so as to repeatedly charge the second capacitor Cx and the first capacitor Cs and subsequently clear the charges on the second capacitor Cx. As the steps B through D are repeated, the charges are increasingly accumulated on the first capacitor Cs, so that the voltage difference across the first capacitor Cs can be more readily measured. The equations used to calculate the capacitance of the second capacitor Cx are the same as those used with respect to Table 1 and, therefore, are not repeated herein.

TABLE 2
Second Voltage is a given DC supply voltage, and First Voltage
is a given DC supply voltage higher than Second Voltage.

| STEP | S1 | S2 | S3 | FUNCTION |
|---|---|---|---|---|
| A | Close | Open | Close | Reset Cs |
| B | Open | Open | Open | Deadtime |
| C | Close, | Open | Open | Charge and |
| | then | | | Charge Transfer |
| | Open | | | |
| D | Open | Close | Open | Hold |
| E | | | | Measure voltage |
| | | | | across Cs |
| F | | | | Repeat BCDE |

In Table 3, the Second Voltage V2 is a given DC supply voltage higher than the First Voltage V1. First, in step A, the third switching element S3 is closed to store a certain amount of charges on Cs. In step C, the third switching element S3 is closed to clear charges on the second capacitor Cx. In step D, the first switching element S1 is closed to transfer a part of the charges on the first capacitor Cs to the second capacitor Cx. The above process is repeated a selected number of times so that the charges on the first capacitor Cs are gradually discharged through the second capacitor Cx. A voltage difference formed across the first capacitor Cs after step A is completed is referred to as Vcs. The equations used to calculate the capacitance of the second capacitor Cx are as follows:

Vcs(1)=Vcs·Cs/(Cs+Cx)

Vcs(n)=Vcs(n−1)·Cs/(Cs+Cx)

ΔVcs(n)=K(Vcs(n−1)−Vcs(n))

K=Cs/(Cs+Cx)

Vcs(N)=Vcs−(ΔVcs(1)+ΔVcs(2)+ΔVcs(3)+ . . . +ΔVcs(N))

where Vcs (N) can be obtained through the voltage measurement, N is a known number of repeating cycles, and Vcs is a known constant. Thus, the capacitance of the second capacitor Cx can be obtained by the above mathematics operation.

TABLE 3
First Voltage is a given DC supply voltage, and Second Voltage
is a given DC supply voltage higher than First Voltage.

| STEP | S1 | S2 | S3 | FUNCTION |
|---|---|---|---|---|
| A | Close | Close | Open | Charge |
| B | Open | Open | Open | Deadtime |
| C | Open | Open | Close, | Hold |
| | | | then Open | |
| D | Close | Open | Open | Charge Transfer |
| E | | | | Measure voltage |
| | | | | across Cs |
| F | | | | Repeat BCDE |

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An apparatus for measuring the capacitance to ground of a conductor, the apparatus comprising:
at least three switching elements including first, second and third switching elements, each of the first, second and third switching elements having both a respective open state and a single respective closed state, one terminal of each of the first, second and third switching elements electrically connected to one of first and second distinct voltages;
a sample capacitor having two terminals and having a given capacitance, one of the two terminals of the sample capacitor electrically connected to another terminal of each of the first, second and third switching elements, a proximal one of the two terminals of the sample capacitor directly electrically connected to one end of a conductor by means not comprising one of the switching elements, the other terminal of the two terminals distal from the conductor, the conductor having an unknown capacitance to ground;
a voltage measurement circuit directly electrically connected to one of the two terminals of the sample capacitor by means not comprising one of the switching elements; and
a controller for operating the first, second and third switching elements so that at any time at least one of the first, second and third switching elements is in its respective open state;
wherein:
the two terminals of the first switching element are connected respectively to the distal terminal of the sample capacitor and the first voltage, the first switching element connects the distal terminal of the sample capacitor to the first voltage when in its closed state and disconnects the distal terminal from the first voltage when in its open state;
the two terminals of the second switching element are connected respectively to the proximal terminal of the sample capacitor and the second voltage, the second switching element connects the proximal terminal of the sample capacitor to the second voltage when in its closed state and disconnects the proximal terminal from the second voltage when in its open state; and
the two terminals of the third switching element are connected respectively to the proximal terminal of the sample capacitor and the first voltage, the third switching element connects the proximal terminal of the sample capacitor to the first voltage when in its closed state and disconnects the proximal terminal from the first voltage when in its open state.

2. The apparatus in accordance with claim 1, wherein the first voltage is a given DC supply voltage, and the second voltage is a given DC supply voltage higher than the first voltage.

3. The apparatus in accordance with claim 1, wherein the second voltage is a given DC supply voltage, and the first voltage is a given DC supply voltage higher than the second voltage.

4. The apparatus in accordance with claim 1, wherein each of the first, second and third switching elements comprises a respective field effect transistor, and the controller comprises a clocked voltage pulse source.

5. The apparatus in accordance with claim 2, wherein each of the first, second and third switching elements comprises a respective field effect transistor, and the controller comprises a clocked voltage pulse source.

6. The apparatus in accordance with claim 3, wherein each of the first, second and third switching elements comprises a respective field effect transistor, and the controller comprises a clocked voltage pulse source.

7. A method for measuring the capacitance to ground of a conductor using a measuring apparatus, the measuring apparatus comprising:
at least three switching elements including first, second and third switching elements, each of the first, second and third switching elements having both a respective open state and a single respective closed state, one terminal of each of the first, second and third switching elements electrically connected to one of first and second distinct voltages;
a sample capacitor having two terminals and having a given capacitance, one of the two terminals of the sample capacitor electrically connected to another terminal of each of the first, second and third switching elements, a proximal one of the two terminals of the sample capacitor directly electrically connected to one end of a conductor by means not comprising one of the switching elements, the other terminal of the two terminals distal from the conductor, the conductor having an unknown capacitance to ground;
a voltage measurement circuit directly electrically connected to one of the two terminals of the sample capacitor by means not comprising one of the switching elements; and
a controller for operating the first, second and third switching elements so that at any time at least one of the first, second and third switching elements is in its respective open state, wherein the two terminals of the first switching element are connected respectively to the distal terminal of the sample capacitor and the first voltage, the first switching element connects the distal terminal of the sample capacitor to the first voltage when in its closed state and disconnects the distal terminal from the first voltage when in its open state; the two terminals of the second switching element are connected respectively to the proximal terminal of the sample capacitor and the second voltage, the second switching element connects the proximal terminal of the sample capacitor to the second voltage when in its closed state and disconnects the proximal terminal from the second voltage when in its open state; the two terminals of the third switching element are connected respectively to the proximal terminal of the sample capacitor and the first voltage, the third switching element connects the proximal terminal of the sample capacitor to the first voltage when in its closed state and disconnects the proximal terminal from the first voltage when in its open state; and wherein, the first voltage is a given DC supply voltage, and the second voltage is a given DC supply voltage higher than the first voltage;
wherein the method for measuring the capacitance to ground of a conductor comprises the steps of:
a) resetting the sample capacitor by closing both the first switching element and the third switching element and opening the second switching element to thereby connect both the distal and proximal terminals of the sample capacitor to the first voltage;
b) opening both the first switching element and the third switching element;
c) closing the second switching element, waiting an interval having a selected duration and thereafter opening the second switching element;
d) charging the sample capacitor by closing the first switching element for an interval having a selected duration;
e) measuring a voltage difference across the sample capacitor using the voltage measurement circuit, the voltage difference representative of the capacitance to ground of the conductor.

8. The method in accordance with claim 7, further comprising a step f), subsequent to step e), of repeating steps b), c), d), e) a selected number of times.

9. The method in accordance with claim 7, further comprising a step d1), intermediate steps d) and e), of repeating steps b), c), d) a selected number of times, wherein the step d1) proceeds to step e) after the selected number of times of the repeating is completed.

10. The method in accordance with claim 7, further comprising a step c0), prior to step c), of changing the amount of the charges on the sample capacitor by a selected amount.

11. A method for measuring the capacitance to ground of a conductor using a measuring apparatus, the measuring apparatus comprising:
at least three switching elements including first, second and third switching elements, each of the first, second and third switching elements having both a respective open state and a single respective closed state, one terminal of each of the first, second and third switching elements electrically connected to one of first and second distinct voltages;
a sample capacitor having two terminals and having a given capacitance, one of the two terminals of the sample capacitor electrically connected to another terminal of each of the first, second and third switching elements, a proximal one of the two terminals of the sample capacitor directly electrically connected to one end of a conductor by means not comprising one of the switching elements, the other terminal of the two terminals distal from the conductor, the conductor having an unknown capacitance to ground;
a voltage measurement circuit directly electrically connected to one of the two terminals of the sample capacitor by means not comprising one of the switching elements; and
a controller for operating the first, second and third switching elements so that at any time at least one of the first, second and third switching elements is in its respective open state, wherein the two terminals of the first switching element are connected respectively to the distal terminal of the sample capacitor and the first voltage, the first switching element connects the distal terminal of the sample capacitor to the first voltage when in its closed state and disconnects the distal terminal from the first voltage when in its open state; the two terminals of the second switching element are connected respectively to the proximal terminal of the sample capacitor and the second voltage, the second switching element connects the proximal terminal of the sample capacitor to the second voltage when in its closed state and disconnects the proximal terminal from the second voltage when in its open state; the two terminals of the third switching element are connected respectively to the proximal terminal of the sample capacitor and the first voltage, the third switching element connects the proximal terminal of the sample capacitor to the first voltage when in its closed state and disconnects the proximal terminal from the first voltage when in its open state; and wherein, the second voltage is a given DC supply voltage, and the first voltage is a given DC supply voltage higher than the second voltage;
wherein the method for measuring the capacitance to ground of a conductor comprises the steps of:
a) resetting the sample capacitor by closing both the first switching element and the third switching element and thereby connecting both the distal and proximal terminals of the sample capacitor to the first voltage;
b) opening all of the first, second, and third switching elements;
c) charging the sample capacitor by closing the first switching element, waiting an interval having a selected duration and thereafter opening the first switching element;
d) closing the second switching element, and waiting a selected interval;
e) measuring a voltage difference across the sample capacitor using the voltage measurement circuit, the voltage difference representative of the capacitance to ground of the conductor.

12. The method in accordance with claim 11, further comprising a step f), subsequent to step e), of repeating steps b), c), d), e) a selected number of times.

13. The method in accordance with claim 11, further comprising a step d1), intermediate steps d) and e), of repeating steps b), c), d) a selected number of times, wherein the step d1) proceeds to step e) after the selected number of times of the repeating is completed.

14. The method in accordance with claim 11, further comprising a step c0), prior to step c), of changing the amount of the charges on the sample capacitor by a selected amount.

15. A method for measuring the capacitance to ground of a conductor using a measuring apparatus, the measuring apparatus comprising:
at least three switching elements including first, second and third switching elements, each of the first, second and third switching elements having both a respective open state and a single respective closed state, one terminal of each of the first, second and third switching elements electrically connected to one of first and second distinct voltages;
a sample capacitor having two terminals and having a given capacitance, one of the two terminals of the sample capacitor electrically connected to another terminal of each of the first, second and third switching elements, a proximal one of the two terminals of the sample capacitor directly electrically connected to one end of a conductor by means not comprising one of the switching elements, the other terminal of the two terminals distal from the conductor, the conductor having an unknown capacitance to ground;
a voltage measurement circuit directly electrically connected to one of the two terminals of the sample capacitor by means not comprising one of the switching elements; and
a controller for operating the first, second and third switching elements so that at any time at least one of the first, second and third switching elements is in its respective open state, wherein the two terminals of the first switching element are connected respectively to the distal terminal of the sample capacitor and the first voltage, the first switching element connects the distal terminal of the sample capacitor to the first voltage when in its closed state and disconnects the distal terminal from the first voltage when in its open state; the two terminals of the second switching element are connected respectively to the proximal terminal of the sample capacitor and the second voltage, the second switching element connects the proximal terminal of the sample capacitor to the second voltage when in its closed state and disconnects the proximal terminal from the second voltage when in its open state; the two terminals of the third switching element are connected respectively to the proximal terminal of the sample capacitor and the first voltage, the third switching element connects the proximal terminal of the sample capacitor to the first voltage when in its closed state and disconnects the proximal terminal from the first voltage when in its open state; and wherein, the first voltage is a given DC supply voltage, and the second voltage is a given DC supply voltage higher than the first voltage;
wherein the method for measuring the capacitance to ground of a conductor comprises the steps of:
a) closing both the first switching element and the second switching element for an interval having a selected duration so that the sample capacitor stores a selected amount of charges;
b) opening both the first and second switching elements;
c) closing the third switching element for an interval having a selected duration and thereafter opening the third switching element;
d) discharging the sample capacitor by closing the first switching element for an interval having a selected duration;
e) measuring a voltage difference across the sample capacitor using the voltage measurement circuit, the voltage difference representative of the capacitance to ground of the conductor.

16. The method in accordance with claim 15, further comprising a step f), subsequent to step e), of repeating steps b), c), d), e) a selected number of times.

17. The method in accordance with claim 15, further comprising a step d1), intermediate steps d) and e), of repeating steps b), c), d) a selected number of times, wherein the step d1) proceeds to step e) after the selected number of times of the repeating is completed.

18. The method in accordance with claim 15, further comprising a step c0), prior to step c), of changing the amount of the charges on the sample capacitor by a selected amount.
